(19) United States
(12) Patent Application Publication
(10) Pub. No.: US 2026/0337008 A1
(43) Pub. Date: Oct. 29, 2026

(54) MICROSCALE FLEXIBLE STRAIN SENSOR

(71) Applicant: CARNEGIE MELLON UNIVERSITY, Pittsburgh, PA (US)

(72) Inventor: Jay Reddy, Pittsburgh, PA (US)

(73) Assignee: CARNEGIE MELLON UNIVERSITY, Pittsburgh, PA (US)

(21) Appl. No.: 19/736,194

(22) Filed: Jul. 9, 2026

Related U.S. Application Data
(63) Continuation of application No. 18/727,548, filed on Mar. 28, 2023, now Pat. No. 12,729,106.
(60) Provisional application No. 63/324,839, filed on Mar. 29, 2022.

(51) Int. Cl. B81B 3/00; B81C 1/00; G01B 7/16

(52) U.S. Cl. CPC B81B 3/007; B81C 1/00682; G01B 7/22; B81B 2201/0292; B81B 2203/0136; B81B 2203/04; B81B 2207/07; B81C 2201/013; B81C 2201/0156; B81C 2201/0174

(57) ABSTRACT

Disclosed herein are devices comprising stretchable interdigitated electrode arrays and methods for fabricating the devices. The devices are capable of acting as elongation sensors by sensing a change in the capacitance of the device as the distance between the interdigitated fingers changes when the device is elongated or compressed. The device may be coupled to other devices such as to be able to sense elongation or compression of the coupled device. The interdigitated fingers of the device are supported by a substrate and may be fabricated using traditional microfabrication techniques.

### RELATED APPLICATIONS

This application is a continuation application filed under 35 U.S.C. § 121 of U.S. patent application Ser. No. 18/727,548, filed Jul. 9, 2024.

U.S. patent application Ser. No. 18/727,548 is a national phase filing under 35 U.S.C. § 371 of International Patent Application No. PCT/US23/16516, filed Mar. 28, 2023.

International Patent Application No. PCT/US23/16516 claims the benefit of U.S. Provisional Patent Application No. 63/324,839, filed Mar. 29, 2022.

The contents of these applications are incorporated herein in their entireties.

### BACKGROUND

Traditional resistive strain gauges measure elongation via changes in resistivity of a metal under strain. However, such sensors are not feasible to detect large amounts of elongation (i.e., ε>0.1), as they are inherently limited by the low stretchability of the constituent metal traces. Recently, interdigitated electrode array (IDE) capacitive strain gauges have been introduced that measure strain via the changing capacitance of interdigitated electrodes as they are moved closer together or further apart.

To be stretchable, these sensors must be implemented using flexible conductive elastomer traces. Due to the molding and printing processes required for these materials, they are not compatible with traditional high-volume MEMS fabrication, and are limited to large feature sizes, requiring large-area sensors. 3D fabrication of out-of-plane wavey substrates has been demonstrated to increase the stretchability of IDE capacitive strain sensors implemented using metal traces, but this also increases the fabrication complexity and thickness of the devices.

### SUMMARY

Described herein is a novel design of a microfabricated thin-film strain sensor and a method of fabricating the sensor. The sensor uses an interdigitated electrode array supported on a flexible substrate with in-plane trace routing to increase the device stretchability along the axis of elongation, with the fabrication accomplished using high-volume MEMS manufacturing techniques.

### BRIEF DESCRIPTION OF THE DRAWINGS

By way of example, a specific exemplary embodiment of the disclosed system and method will now be described, with reference to the accompanying drawings, in which:

FIG. 1A is a schematic representation of a sensor in a neutral position; FIG. 1B is a schematic representation of the sensor in an elongated position.

FIG. 2 shows the design of a large-scale sensor fabricated in accordance with embodiments disclosed herein.

FIG. 3 shows steps (a-h) in one possible manufacturing process of the sensor.

### DETAILED DESCRIPTION

The IDE capacitive strain sensor is implemented via an n-finger IDE characterized by the finger width w, inter-finger gap g, finger height t, and finger length L. The number of fingers, finger width, inter-finger gap, finger height and finger length may be customized for different applications based on the sensitivity and area requirements of the sensor, as well as the fabrication resolution. There are trade-offs for selecting various parameters for the device. For example, increasing the number of fingers, the width of the fingers and the length of the fingers will increase the sensitivity of the device at the expense of a larger surface area. Smaller finger width and small gap sizes are desirable because of the reduced surface area of the device but are more expensive to microfabricate due to the need for finer manufacturing resolution and tighter tolerances. Thicker fingers also increase the sensitivity but increase the expense and complexity of thin-film fabrication, as well as increasing the device stiffness.

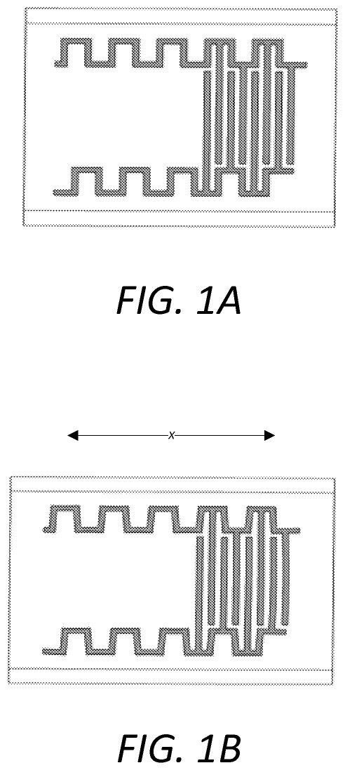

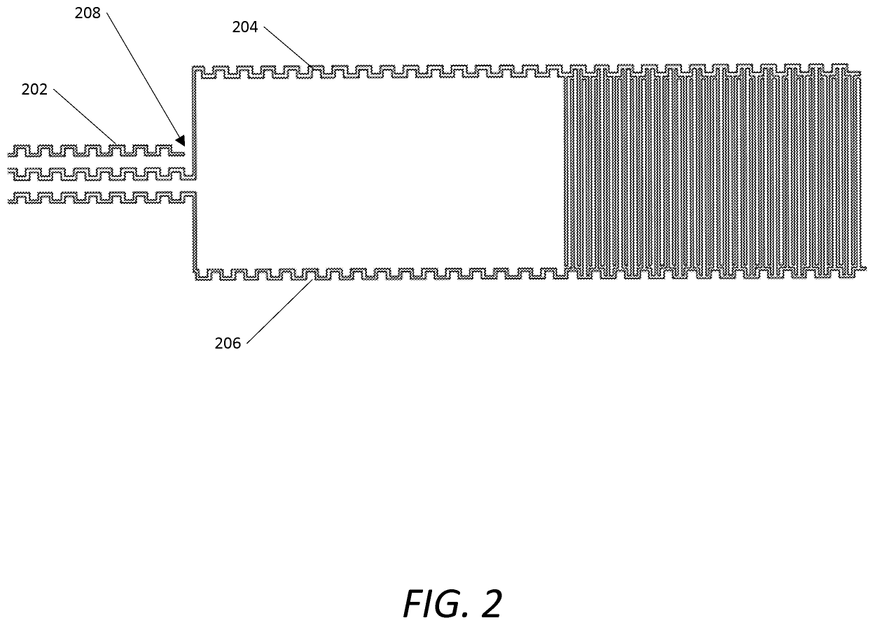

Rather than using straight traces to connect the interdigitated fingers (i.e., ground and sense fingers) of the IDE, the design of embodiments disclosed herein make use of in-plane trace routing to reduce the stiffness of the sensor along the axis of elongation. An exemplary embodiment using a 1st order rectangular routing scheme is shown in FIG. 1A, showing the sensor in the neutral position. FIG. 1B shows the sensor of FIG. 1A in a position of partial elongation along the longitudinal axis (X). The rectangular trace routing reduces strain on the traces when the sensor is elongated. In other embodiments, higher-order self-similar routing and serpentine configurations may also be used. A first trace, shown as reference 204 in FIG. 2, is electrically coupled to a first sub-plurality of the fingers and a second trace, shown as reference 206 in FIG. 2, is electrically-coupled to a second sub-plurality of the fingers, wherein the first and second sub-pluralities are exclusive of each other. In embodiments disclosed herein one trace is a ground trace and the other trace is a sense trace. Preferably, fingers in the first sub-plurality will be disposed between two fingers in the second plurality (except at the ends of the array) and vise-versa, thus forming two sets of interdigitated fingers.

FIG. 2 shows an exemplary large-scale sensor fabricated in accordance with techniques disclosed herein. In this example, there are n=100 fingers. The sensor design is highly sensitive to parasitic capacitances. Therefore, the sensor can be employed in a single-ended sensing configuration or in a differential sensing configuration, where a 3rd reference trace 202 is routed in the cable and used in a differential scheme to compensate for the parasitic capacitance of the trace routing in a cable connecting the device to sensing circuitry, which can be considerable and may be highly-dependent on the environment in which the sensor is deployed. The reference trace 202 runs along trace 206 and through the cable. In the differential scheme, the capacitance is measured from the sensor plus the cable, and also from the cable alone, and the capacitance of the sensor can be isolated by taking the difference between the two measured capacitances. In some embodiments, reference trace 202 may be coupled (at location 208, for example) with a purposeful capacitor (i.e., a capacitor of a known capacitance) or other electrical element. The reference trace 202 is constructed in electrically conductive layer 108 and also exhibits self-similar routing, similar to the first and second traces.

Sensors in accordance with embodiments disclosed herein may be attached to various devices, for example, cochlear implants or catheters, to measure device deflection and forces exerted on the device. In various embodiments, multiple sensors can be employed in an array to achieve localized strain measurement. In yet other embodiments, different orientations of the sensors can be used to differentiate strain along multiple axes. For example, sensors may be placed having orthogonal axes of elongation such as to capture elongation in both “X” and “Y” directions. In yet other embodiments, the sensors may be placed at an angle relative to the axis of elongation such as to be able to sense elongation along both axes.

To measure the change in capacitance of the device, the device may be coupled to capacitive sensing circuitry (not shown) which is commercially available as an off-the-shelf item.

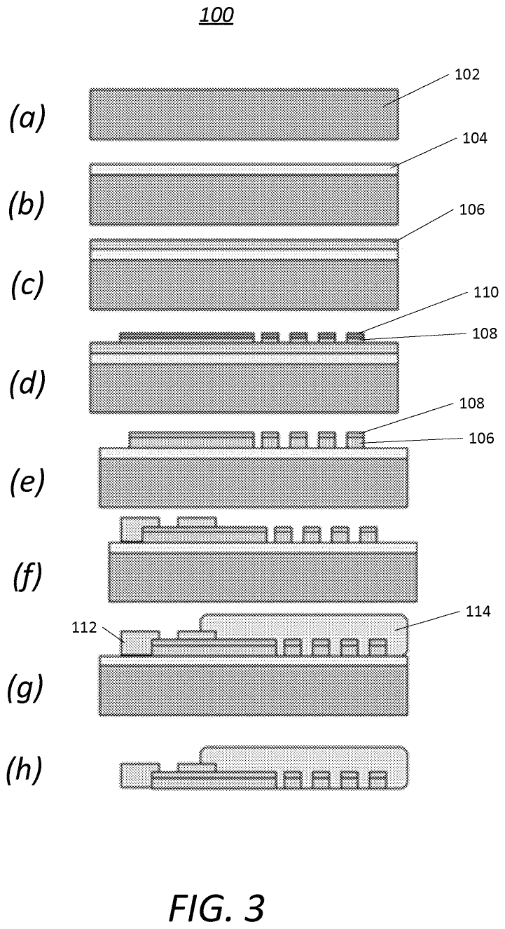

An exemplary microfabrication process 100 to fabricate sensors in accordance with embodiments disclosed herein is shown in FIG. 3, which shows a cross-sectional view of the device in various stages of the fabrication process.

The process begins with a wafer 102 shown step (a). In preferred embodiments, wafer 102 is Si, although any suitable material may be used. In step (b), a release layer 104 is deposited on wafer 102. In one embodiment, release layer 104 may be composed of, for example, Ge, and may be 100 nm in height. As would be realized, any alternative release material known to those of skill in the art could be used. Release layer 104 may be sputtered onto the surface of wafer 102 or deposited via other similar methods (i.e., evaporation, chemical vapor deposition, or spin-coating).

In step (c), a substrate layer 106 is then deposited on release layer 104. In preferred embodiments, substrate layer 106 may be composed of a flexible polymer, for example, Parylene C. However, as would be realized by one of skill in the art, other materials may also be used for substrate layer 106, including, for example, silicone, SU-8, polyamide, SiO₂, SiN, PTFE, PET, PMMA, polyethylene, or similar materials. Substrate layer 106 may preferably be 2 microns in height, although other heights may be used. A thicker substrate layer 106 will add desirable mechanical robustness to the finger traces at the expense of the overall flexibility of the device. In some embodiments, the release layer 104 may be treated to increase adhesion to substrate layer 106 (i.e., using Silane A174 or an appropriate adhesion promotor for the chosen substrate material).

In step (d), an electrically conductive layer 108 is first deposited which will form the electrically conductive portions of the first and second traces 204, 206 and the reference trace 202. The electrically conductive layer 108 may be composed of, in various embodiments, Pt, Au, Cu, or combinations thereof. For example, electrically conductive layer 108 may be a 100 nm layer of Pt or may be a 5 nm layer of Pt and a 100 nm layer of Au. A hardmask trace 110 is then deposited over the electrically conductive layer 108. In alternate embodiments, the electrically conductive layer 108 may be Al, PEDOT or stacks of other conductive materials.

The hardmask 110 may be, for example, a 40 nm layer of Cr, however, as would be realized by one of skill in the art, other materials may also be used, for example, Al, photoresist, SiO₂, etc.

The trace geometry of the interdigitated electrode array is lithographically-defined and a trace stack of the electrically-conductive layer 108 and the hardmask 110 (e.g., Pt/Cr) is evaporated and lifted off. The lift-off process leaves individual stacks forming the fingers of the device and consisting of the substrate material 106 (e.g., Parylene C), the electrically-conductive layer 108 (i.e., Pt or Au) and the hardmask (e.g., Cr), as shown in step (d) in FIG. 3. In such an embodiment, Pt forms the trace material, whereas Cr is a hardmask for patterning the substrate layer 106, which is etched using the Cr hardmask. Etching may be performed using reactive ion etching, wet etching, or similar technique. Alternatively, the fingers may be formed via plasma or chemical etching or laser ablation.

The hardmask 110 is then stripped in step (e), leaving stacks consisting of material from the substrate layer 106 and the electrically-conductive layer 108 forming each of the plurality of fingers. The substrate layer 106 (e.g., Parylene C) only remains under the interdigitated electrode array fingers 108, and any of traces 202, 204, 206.

In step (f) of the process, optional stiffeners 112 may be added to the backend of the device to add strength once the device is released from the wafer 102. In preferred embodiments, stiffeners 112 may be composed of a negative photoresist (e.g., SU-8) and may be applied using lithography. In other embodiments, stiffeners 112 may be composed of Si, SiN, SU-8, Polyimide, Parylene C, or similar materials. In preferred embodiments, stiffeners 112 may be 7 microns in height, but as would be realized by one of skill in the art, any height is acceptable in accordance with the intended use of the device. Stiffeners 112 may be directly printed onto specific regions of the device or deposited and then patterned (i.e., via lithography, wet or dry etching, lift-off, or similar lithographically). In some embodiments, stiffeners 112 may be patterned to expose one or more bondpads to allow electrical connections thereto the first and second traces and the reference trace.

In step (g), the tops of the traces are encapsulated in layer 114. In one embodiment, encapsulation layer 114 is composed of silicone (polydimethylsiloxane—PDMS) which is spin-coated on the surface to form a substrate after release and insulate the tops of the traces. The encapsulation layer 114 extends between the interdigitated fingers of the sensor. Encapsulation layer 114 may be lithographically patterned and etched or lifted-off to expose the bondpads. The backend bondpads of the sensor may also be protected via Kapton tape or other means during PDMS deposition.

In step (h) the device is released from the silicon wafer 102 by laser-cutting the outline into the encapsulation layer 114 and dissolving the release layer 104. Alternative methods for patterning the encapsulation layer include patterning via wet or dry etching or liftoff. For example, in an embodiment wherein release layer 104 is Ge, a hydrogen peroxide solution may be used to dissolve the Ge.

The sensor may be adhered to other devices (i.e., the devices that are to be sensed, for example, a cochlear implant or catheter) by an adhesive, for example, a silicone adhesive, or the sensor may be incorporate directly into the manufacturing process of the sensed device. Alternatively, any means of coupling the sensor to the sensed device may be used.

The invention is contemplated to include both the devices and the process for manufacturing a multilayered device as described herein using microfabrication techniques. As would be realized by one of skill in the art, many variations on the process disclosed herein are possible and are contemplated to be within the scope of the invention. The scope of the invention is defined by the claims which follow.

1. A method of forming a microfabricated interdigitated electrode array, the method comprising:
depositing a release layer on a wafer;
depositing a substrate layer composed of a polymer on the release layer;
depositing a trace layer of an electrically-conductive material on the substrate layer;
depositing a hardmask layer on the trace layer;
patterning the hardmask layer to define a plurality of interdigitated fingers and a plurality of electrical traces;
removing material from the hardmask layer, the trace layer, and the substrate layer not forming a part of the plurality of interdigitated fingers or the plurality of electrical traces; and
dissolving the release layer to release the microfabricated interdigitated electrode array from the wafer.

2. The method of claim 1, further comprising:
depositing an encapsulation layer prior to the release of the microfabricated interdigitated electrode array, the encapsulation layer covering the plurality of interdigitated fingers and at least partially covering the plurality of electrical traces;
wherein the encapsulation layer extends between the interdigitated fingers.

3. The method of claim 2, wherein the encapsulation layer is composed of PDMS.

4. The method of claim 2, further comprising:
depositing one or more stiffeners prior to the release of the microfabricated interdigitated electrode array, the one or more stiffeners covering at least a portion of the plurality of electrical traces.

5. The method of claim 4, wherein the one or more stiffeners are etched to expose one or more bondpads electrically coupled to the plurality of electrical traces.

6. The method of claim 4, wherein the one or more stiffeners are composed of SU-8.

7. The method of claim 1, wherein the plurality of electrical traces comprise:
a first electrically-conductive trace coupled to a first sub-plurality of the fingers; and
a second electrically-conductive trace coupled to a second sub-plurality of the fingers;
wherein the first and second sub-pluralities of fingers are exclusive of each other.

8. The method of claim 7, wherein the plurality of electrical traces further comprise:
a reference trace.

9. The method of claim 1, wherein the substrate layer is composed of a flexible polymer.

10. The method of claim 9, wherein the flexible polymer is Parylene C.

11. The method of claim 1, wherein the plurality of interdigitated fingers and the plurality of electrical traces are formed via a lift-off process, plasma etching, chemical etching, or laser ablation.

12. The method of claim 1, further comprising:
removing the remaining hardmask layer prior to dissolving the release layer.

13. The method of claim 1 wherein each of the plurality of interdigitated fingers is able to move with respect to each other along a longitudinal axis of the electrode array.

14. A method of forming a microfabricated interdigitated electrode array, the method comprising:
depositing a substrate layer composed of a polymer over a wafer;
depositing a trace layer of an electrically-conductive material on the substrate layer;
removing material from the trace layer and the substrate layer to define a plurality of interdigitated fingers and a plurality of electrical traces; and
releasing the microfabricated interdigitated electrode array from the wafer;
wherein, after the removing, the substrate layer remains only under the plurality of interdigitated fingers and the plurality of electrical traces.

15. The method of claim 14, wherein the polymer is Parylene C.

16. The method of claim 14, wherein the electrically-conductive material comprises platinum, gold, or a stack comprising layers of platinum and gold.

17. The method of claim 14, wherein the plurality of electrical traces comprise:
a first electrically-conductive trace coupled to a first sub-plurality of the interdigitated fingers;
a second electrically-conductive trace coupled to a second sub-plurality of the interdigitated fingers; and
a reference trace;
wherein the first and second sub-pluralities of the interdigitated fingers are exclusive of each other.

18. The method of claim 14 wherein each of the plurality of interdigitated fingers is able to move with respect to each other along a longitudinal axis of the electrode array.

19. A method of forming a microfabricated device, the method comprising:
depositing a release layer on a wafer;
depositing a substrate layer composed of a flexible polymer on the release layer;
forming a plurality of interdigitated fingers and a plurality of electrical traces from a trace layer of an electrically-conductive material deposited on the substrate layer;
depositing an electrically-insulating encapsulation layer covering the plurality of interdigitated fingers, the encapsulation layer extending between the interdigitated fingers; and
dissolving the release layer to release the microfabricated device from the wafer.

20. The method of claim 19, wherein the encapsulation layer is composed of PDMS.

21. The method of claim 19, further comprising:
depositing one or more stiffeners prior to releasing the microfabricated device, the one or more stiffeners covering at least a portion of the plurality of electrical traces.

22. The method of claim 19, wherein changing an elongation of the microfabricated device causes the microfabricated device to exhibit a change in capacitance.

23. The method of claim 19 wherein each of the plurality of interdigitated fingers is able to move with respect to each other along a longitudinal axis of the electrode array.
